(19) United States
(12) Patent Application Publication
(10) Pub. No.: US 2008/0093723 A1
(43) Pub. Date: Apr. 24, 2008

(54) Passive placement in wire-bonded microelectronics

(76) Inventors: Todd B. Myers, Gilbert, AZ (US); Chunho Kim, Phoenix, AZ (US); Seung Ae Lee, Chandler, AZ (US); Suresh B. Yeruva, Chandler, AZ (US)

Correspondence Address: INTEL CORPORATION;c/o INTELLEVATE, LLC, P.O. BOX 52050, MINNEAPOLIS, MN, 55402, US

(21) Appl. No.: 11/584,383

(22) Filed: Oct. 19, 2006

(51) Int. Cl. H01L 23/02; H01L 21/00

(52) U.S. Cl. 257/686; 438/109; 257/E23.085

(57) ABSTRACT

A microelectronic assembly includes a first microelectronic device electrically coupled with a second microelectronic device via wire bond attachment, the first microelectronic device being structurally coupled with the second microelectronic device via a polymer adhesive, and one or more passive(s) coupled with the first microelectronic device wherein at least one or more passive(s) are enclosed in the polymer adhesive between the first and second microelectronic devices.

### TECHNICAL FIELD

Embodiments of the present invention are generally directed to the field of microelectronic packaging and, more particularly, to passive placement in wirebonded microelectronics.

### BACKGROUND

In microelectronic packaging, microelectronic devices such as integrated circuit (IC) dies, chipsets, and/or memory are commonly attached to a package substrate using a wire-bonding technique to attach very fine wire from metallized terminal pads along the periphery of the microelectronic device to corresponding bonding pads on the surface of the package substrate. The package substrate often has passive components coupled with the package substrate on the area of the package substrate external to the wire bonds to avoid interference with wire bond connections. Such passive placement occupies valuable shrinking area on the package substrate as innovations in semiconductor manufacturing demand ever smaller dimensions in package size. Novel solutions for passive placement are needed to accommodate shrinking dimensions of microelectronic packages.

### BRIEF DESCRIPTION OF THE DRAWINGS

Embodiments of the present invention are illustrated by way of example, and not by way of limitation, in the figures of the accompanying drawings in which like reference numerals refer to similar elements and in which:

FIG. 1 is a diagram of a microelectronic assembly (Prior Art);

FIG. 2 is a diagram of a microelectronic assembly, according to but one embodiment;

FIG. 3 is another diagram of a microelectronic assembly, according to but one embodiment;

FIG. 4 is a flow diagram illustrating a method for fabricating a microelectronic assembly, according to but one embodiment; and

FIG. 5 is a diagram illustrating an example system in which embodiments of the present invention may be used.

### DETAILED DESCRIPTION

Embodiments of a microelectronic assembly, associated methods, and systems are described herein. In the following description, numerous specific details are set forth to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring the specification.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment. Furthermore, the particular features, structures or characteristics may be combined in any suitable manner in one or more embodiments.

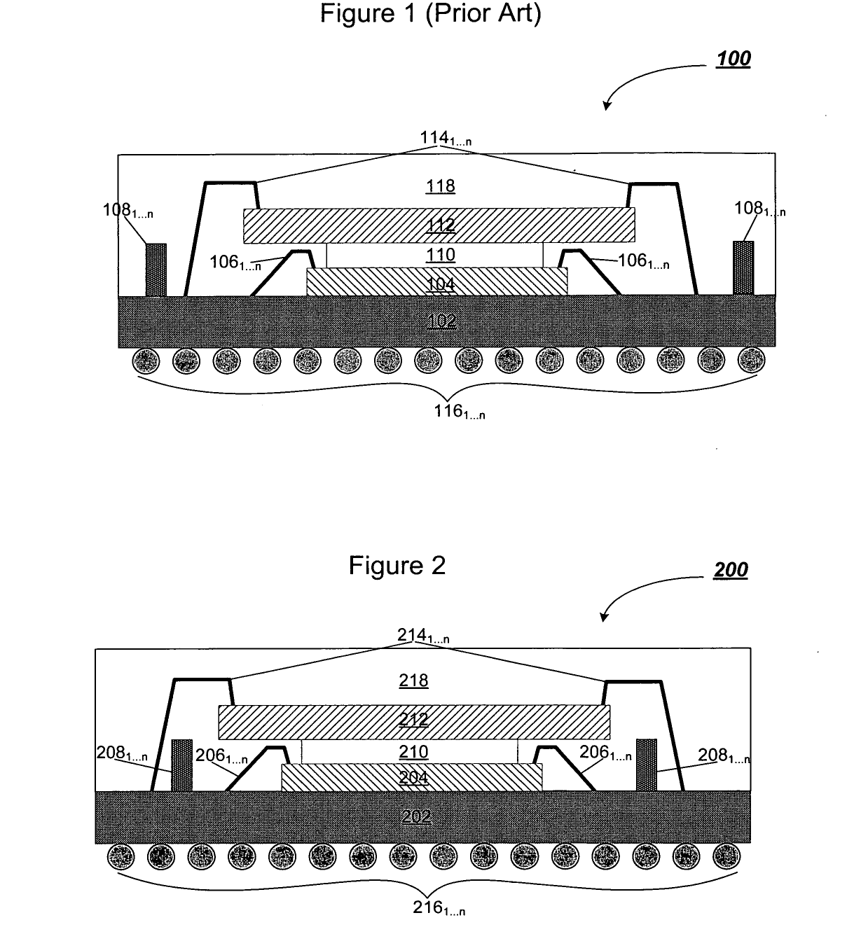

FIG. 1 is a diagram of a microelectronic assembly (Prior Art) 100. A microelectronic assembly 100 includes a first microelectronic device 102 such as a package substrate, a second microelectronic device 104, one or more wire bond(s) 106_{1 . . . n} (where n represents a variable number of repeating structures), one or more passive(s) 108_{1 . . . n}, a spacer 110, a third microelectronic device 112, one or more wire bond(s) 114_{1 . . . n}, array of solder balls 116_{1 . . . n}, and mold compound 118, each coupled as shown, according to one embodiment.

As depicted, assembly 100 includes one or more passives 108_{1 . . . n} coupled to an area of a package substrate 102 external to one or more wire bond(s) 106_{1 . . . n}, 114_{. . . n}. In other words, one or more passives 108_{1 . . . n} are currently placed on an area of substrate 102 more distant from the microelectronic devices 104, 112 than the location on the substrate 102 where the one or more wire bond(s) 106_{1 . . . n}, 114_{. . . n} are attached to the substrate 102. Shrinking designs in microelectronic packages such as assembly 100 are limiting the available area (i.e. −x and y footprint) of substrate 102 where passives 108_{1 . . . n} are currently attached.

FIG. 2 is a diagram of a microelectronic assembly 200, according to but one embodiment. A microelectronic assembly 200 includes a first microelectronic device such as a package substrate 202, a second microelectronic device 204, one-or more wire bond(s) 206_{1 . . . n} (where n represents a variable number of repeating structures), one or more passive(s) 208_{1 . . . n}, a spacer 210, a third microelectronic device 212, one or more wire bond(s) 214_{1 . . . n}, and array of solder balls 216_{1 . . . n}, and mold compound 218, each coupled as shown, according to one embodiment.

In one embodiment, a microelectronic assembly 200 includes one or more passive(s) 208_{1 . . . n} coupled to an area of substrate 202 that is closer to microelectronic device(s) 204 or 212 than the location where associated wire bond(s) 206_{1 . . . n} or 214_{. . . n} are coupled to substrate 202. Passive 208_{1 . . . n} placement under wire bond loop 214_{. . . n}, as depicted, may accommodate smaller substrate 202 dimensions. While such embodiment utilizes previously unused surface area on substrate 202 for passive attachment, passive(s) 208_{1 . . . n} placed under the wire loops 214_{. . . n} as depicted may increase risk of electrical interference such as shorting between microelectronic devices 204, 212, wire bonds 206_{1 . . . n}, 214_{. . . n}, and passive(s) 208_{1 . . . n}.

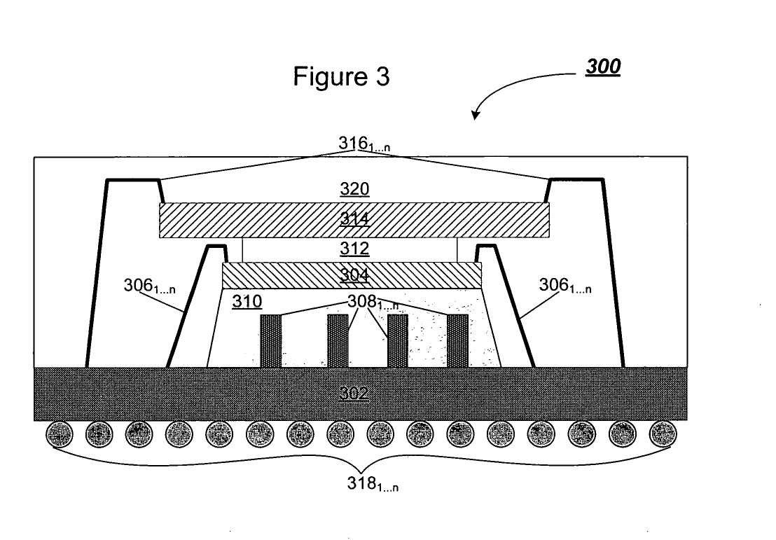

FIG. 3 is another diagram of a microelectronic assembly 300, according to but one embodiment. A microelectronic assembly 300 includes a first microelectronic device 302 such as a package substrate, a second microelectronic device 304, one or more wire bond(s) 306_{1 . . . n} (where n represents a variable number of repeating structures), one or more passive(s) 308_{1 . . . n}, a polymer adhesive 310, a spacer 312, a third microelectronic device 314, one or more wire bond(s) 316_{. . . n}, array of solder balls 318_{. . . n}, and mold compound 320, each coupled as shown, according to one embodiment.

In one embodiment, assembly 300 includes a first microelectronic device 302 and a second microelectronic device 304 electrically coupled with the first microelectronic 302 device via wire bond attachment using one or more wire(s) 306_{1 . . . n}. In an embodiment, one or more passive(s) 308_{1 . . . n} are coupled to a first microelectronic device 302 on a surface region of device 302 such that the passive(s) 308_{1 . . . n} are located between a first 302 and second 304 microelectronic device. An area between a first 302 and second 304 microelectronic device includes the area on a package substrate in the die shadow where a first microelectronic device 302 is a package substrate and a second microelectronic device 304 is an IC die, according to one embodiment. A die shadow is the equivalent die surface area on the surface of a package substrate 302 that is closest to the die 304 when the die 304 and substrate are in a coupled arrangement.

In an embodiment, a second microelectronic device 304 is coupled with a first microelectronic device 302 using a polymer adhesive 310. In one embodiment, polymer adhesive 310 structurally couples a second microelectronic device 304 with a first microelectronic device 302. In another embodiment, polymer adhesive 310 encloses or encapsulates one or more passive(s) 308_{1 . . . n} coupled with the first microelectronic device. In one embodiment, polymer adhesive 310 encloses or encapsulates one or more passive(s) 308_{1 . . . n} between the first 302 and second microelectronic devices 304. In another embodiment, polymer adhesive 310 is in the die shadow of a second microelectronic device 304 wherein the second microelectronic device 304 is an IC die.

A polymer adhesive 310 includes a die-attach epoxy according to an embodiment. In another embodiment, a polymer adhesive 310 electrically insulates the one or more passive(s) 308_{1 . . . n}. In other embodiments, a polymer adhesive 310 is selected for its adhesive properties, electrically insulative properties, and compatibility with materials associated with microelectronic devices 302, 304 and one or more passive(s) 308_{1 . . . n}.

One or more passive(s) 308_{1 . . . n} include surface mount technology (SMT) passives according to one embodiment. In another embodiment, one or more passive(s) 308_{1 . . . n} include resistors, inductors, capacitors, and other analogous passive electrical components. In an embodiment, passive(s) 308_{1 . . . n} are coupled with substrate 302 by solder joint(s). In other embodiments, assembly 300 also incorporates passives as described in assemblies 100 and 200.

An assembly 300 may comprise a variety of microelectronic devices 302, 304, 314. In one embodiment, first microelectronic device 302 is a substrate. Substrate 302 is electrically coupled with another device not depicted in assembly 300 according to one embodiment. In one embodiment, substrate 302 is electrically coupled with another device such as memory via array of solder balls 318_{1 . . . n}. A second microelectronic device 304 is an IC die, chipset, or memory in one embodiment.

Assembly 300 includes a substrate 302 coupled with a second 304 and third 314 microelectronic device in an arrangement as depicted, according to an embodiment. A spacer 312 is coupled with a second microelectronic device 304. Spacer 312 is dummy silicon according to one embodiment. Spacer 312 thickness provides sufficient area to prevent contact between wires 306_{1 . . . n} and a third microelectronic device 314 coupled with the spacer according to one embodiment. A third microelectronic device 314 is electrically coupled to the first microelectronic device 302 via wire bond attachment using one or more wire(s) 316_{. . . n}. In one embodiment, third microelectronic device 314 is an IC die, chipset, or memory device. Assembly 300 may include a substrate 302 that is further coupled with other microelectronic devices using an analogous stacking arrangement as depicted here with microelectronic devices 304, 314 and spacer 312.

In an embodiment, second microelectronic device 304, spacer 312, third microelectronic device 314, one or more wire bond(s) 306_{1 . . . n}, 316_{1 . . . n} associated with the second and third microelectronic devices 304, 314, respectively, and the one or more passive(s) 308_{1 . . . n} are enclosed or encapsulated in a mold compound 320 that is coupled to at least one surface of the first microelectronic device 302.

Assembly 300 may accommodate shrinking design requirements for package substrate 302 by placing passives between an IC die 304 and substrate 302. Placing passives between a substrate 302 and IC die 304, for example, may enable the addition of more passives to the package by utilizing the space in the die shadow. Furthermore, such embodiments may potentially shorten electrical paths from an IC die 304 to board by enabling reduced package dimensions.

In an embodiment, assembly 300 includes wire-bonded ICs 304, 314 that are integrated with passives 308_{1 . . . n} in the package. In one example embodiment, assembly 300 includes memory die stacks 304, 314 such as memory cards using NAND (Not AND) silicon that include passive components 308_{1 . . . n}. In another embodiment, assembly 300 includes radio frequency (RF) devices 304, 314 such as RF laminate modules that include passive components 308_{1 . . . n}. Other systems, devices, and components may be coupled with microelectronic assembly 300 as described in system 500.

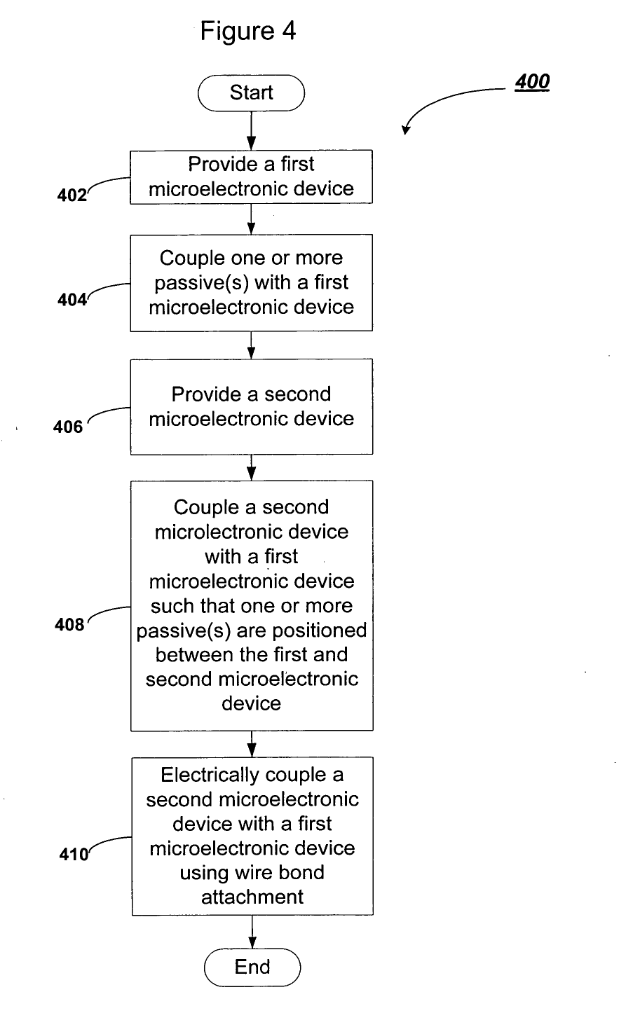

FIG. 4 is a flow diagram illustrating a method 400 for fabricating a microelectronic assembly, according to but one embodiment. Method 400 includes providing a first microelectronic device 402, coupling one or more passives with a first microelectronic device 404, providing a second microelectronic device 406, coupling a second microelectronic device with a first microelectronic device such that one or more passive(s) are positioned between the first and second microelectronic device 408, and electrically coupling a second microelectronic device with a first microelectronic device using wire bond attachment 410, according to one embodiment.

Providing a first microelectronic device 402 includes providing a package substrate according to one embodiment. According to an embodiment, providing a first microelectronic device includes preparing a first microelectronic device for coupling with other components and receiving a first microelectronic device with manufacturing equipment.

Coupling one or more passive(s) with a first microelectronic device 404 includes coupling one or more surface mount technology (SMT) passives including resistors, inductors, capacitors, and analogous passive components in an embodiment. One or more passives may be coupled with the package substrate 404 by a solder process or any other suitable attachment method. In an embodiment, one or more passive(s) are coupled with a surface region of first microelectronic device 404 such that the passive(s) are located between a first and second microelectronic device in a finished package assembly. A surface region of a first microelectronic device includes the area on a package substrate in the die shadow where a first microelectronic device is a package substrate and a second microelectronic device is an IC die, according to one embodiment. A die shadow is the equivalent die surface area on the surface of a package substrate that is closest to the die when the die and substrate are in a coupled arrangement such as in a finished package.

Providing a second microelectronic device 406 includes providing an IC die, chipset, or memory device according to one embodiment. According to an embodiment, providing a second microelectronic device 406 includes preparing a second microelectronic device for coupling and receiving a second microelectronic device with manufacturing equipment.

Coupling a second microelectronic device with a first microelectronic device such that one or more passive(s) are positioned between the first and second microelectronic device 408 includes structurally coupling the first and second devices using polymer adhesive. In an embodiment, a polymer adhesive is used to couple a first and second microelectronic device such that one or more passives are positioned between the first and second microelectronic device 408. In another embodiment, polymer adhesive encloses or encapsulates the one or more passives positioned between the first and second microelectronic device. Polymer adhesive is a die-attach epoxy according to an embodiment. In another embodiment, polymer adhesive electrically insulates one or more passives.

Electrically coupling a second microelectronic device with a first microelectronic device using wire bond attachment 410 includes any suitable wire bond attachment method. In one embodiment, very fine wire, typically Al or Au, is attached from metallized terminal pads along the periphery of an integrated circuit chip to corresponding bonding pads on the surface of the package. In an embodiment, attachment is accomplished by thermal compression. In another embodiment, attachment is accomplished by ultrasonic welding.

In other embodiments of method 400, a spacer is coupled with the second microelectronic device. A spacer may accord with embodiments described above in assembly 300. Method 400 may further include providing a third microelectronic device. According to an embodiment, lo providing a third microelectronic device includes preparing a third microelectronic device for attachment and receiving a second microelectronic device with manufacturing equipment for attachment. In an embodiment, third microelectronic device is an IC die, chipset, or memory device.

In an embodiment, a third microelectronic device is coupled with a spacer. In another embodiment, a third microelectronic device is electrically coupled with the first microelectronic device via wire bond attachment using one or more wire(s).

In another embodiment, method 400 includes enclosing the second microelectronic device, the spacer, the third microelectronic device, the one or more wire bond(s) associated with the second and third microelectronic device, and the one or more passive(s) in a mold compound that is coupled to the first microelectronic device.

In other embodiments, method 400 incorporates embodiments of assembly components described for assemblies 200 and 300.

Various operations may be described as multiple discrete operations in turn, in a manner that is most helpful in understanding the invention. However, the order of description should not be construed as to imply that these operations are necessarily order dependent. In particular, these operations need not be performed in the order of presentation. Operations described may be performed in a different order than the described embodiment. Various additional operations may be performed and/or described operations may be omitted in additional embodiments.

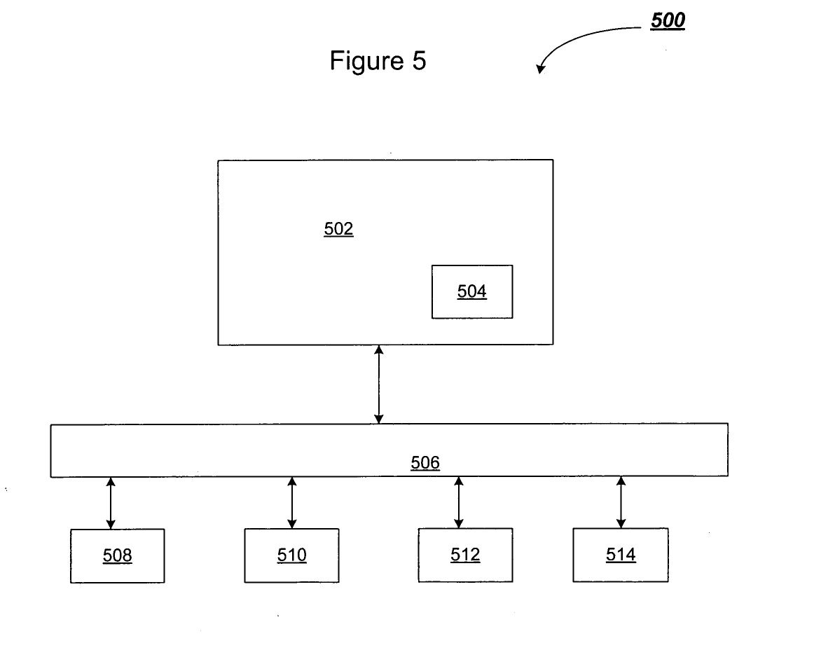

FIG. 5 is a diagram illustrating an example system in which embodiments of the present invention may be used. In one embodiment, an electronic assembly 502 includes a microelectronic assembly 504 that accords with assemblies 100, 200, and/or 300 and the various embodiments as described herein. Assembly 502 may further include another microelectronic device or assembly, such as a microprocessor or multiple microprocessors. In an alternate embodiment, the electronic assembly 502 may include an application specific IC (ASIC) or multiple ASICs. Integrated circuits found in chipsets (e.g., graphics, sound, and control chipsets) may also be packaged in accordance with embodiments of this invention.

For the embodiment depicted by FIG. 5, the system 500 may also include a main memory 508, a graphics processor 510, a mass storage device 512, and/or an input/output module 514 coupled to each other by way of a bus 506, as shown. Examples of the memory 508 include but are not limited to static random access memory (SRAM) and dynamic random access memory (DRAM). Examples of the mass storage device 512 include but are not limited to a hard disk drive, a compact disk drive (CD), a digital versatile disk drive (DVD), and so forth. Examples of the input/output module 514 include but are not limited to a keyboard, cursor control arrangements, a display, a network interface, and so forth. Examples of the bus 506 include but are not limited to a peripheral control interface (PCI) bus, and Industry Standard Architecture (ISA) bus, and so forth. In various embodiments, the system 500 may be a wireless mobile phone, a personal digital assistant, a pocket PC, a tablet PC, a notebook PC, a desktop computer, a set-top box, a media-center PC, a DVD player, or a server.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various equivalent modifications are possible within the scope of the invention, as those skilled in the relevant art will recognize.

These modifications can be made to the invention in light of the above detailed description. The terms used in the following claims should not be construed to limit the invention to the specific embodiments disclosed in the specification and the claims. Rather, the scope of the invention is to be determined entirely by the following claims, which are to be construed in accordance with established doctrines of claim interpretation.

What is claimed is:

1. A microelectronic assembly comprising:
a first microelectronic device;
a second microelectronic device electrically coupled with the first microelectronic device via wire bond attachment using one or more wire(s), the second microelectronic device being structurally coupled with the first microelectronic device via a polymer adhesive; and
one or more passive(s) coupled with the first microelectronic device, the one or more passive(s) enclosed in the polymer adhesive between the first and second microelectronic devices.

2. A microelectronic assembly according to claim 1, wherein the one or more passive(s) are surface mount technology (SMT) passives including resistors, inductors, and capacitors.

3. A microelectronic assembly according to claim 1, wherein the polymer adhesive comprises a die-attach epoxy that electrically insulates the one or more passive(s).

4. A microelectronic assembly according to claim 1, wherein the first microelectronic device is a package substrate and the second microelectronic device is an integrated circuit (IC) die.

5. A microelectronic assembly according to claim 1, further comprising:
a spacer coupled with the second microelectronic device; and
a third microelectronic device coupled with the spacer, the third microelectronic device electrically coupled to the first microelectronic device via wire bond attachment using one or more wire(s).

6. A microelectronic assembly according to claim 5 wherein the spacer comprises dummy Si and the third microelectronic device is an integrated circuit (IC) die.

7. A microelectronic assembly according to claim 5, wherein the second microelectronic device, the spacer, the third microelectronic device, the one or more wire bond(s) associated with the second and third microelectronic device, and the one or more passive(s) are enclosed in a mold compound that is coupled to the first microelectronic device.

8. A method comprising:
providing a first microelectronic device;
coupling one or more passive(s) with the first microelectronic device;
providing a second microelectronic device;
structurally coupling the second microelectronic device with the first microelectronic device using polymer adhesive such that one or more of the coupled passive(s) are positioned between the first and second microelectronic device, the polymer adhesive enclosing the one or more coupled passive(s) positioned between the first and second microelectronic device; and
electrically coupling the second microelectronic device with the first microelectronic device via wire bond attachment using one or more wire(s).

9. A method according to claim 8, wherein coupling one or more passive(s) comprises coupling one or more surface mount technology (SMT) passives including resistors, inductors, and capacitors.

10. A method according to claim 8, wherein the polymer adhesive comprises a die-attach epoxy that electrically insulates the one or more passive(s).

11. A method according to claim 8, wherein providing a first microelectronic device comprises providing a package substrate and providing a second microelectronic device comprises providing an integrated circuit (IC) die.

12. A method according to claim 8, further comprising:
coupling a spacer with the second microelectronic device;
providing a third microelectronic device;
coupling the third microelectronic device with the spacer; and
electrically coupling the third microelectronic device with the first microelectronic device via wire bond attachment using one or more wire(s).

13. A method according to claim 12 wherein the spacer comprises dummy Si and the third microelectronic device is an IC die.

14. A method according to claim 12, further comprising:
enclosing the second microelectronic device, the spacer, the third microelectronic device, the one or more wire bond(s) associated with the second and third microelectronic device, and the one or more passive(s) in a mold compound that is coupled to the first microelectronic device.

15. A microelectronic system comprising:
a first microelectronic device;
a second microelectronic device electrically coupled with the first microelectronic device via wire bond attachment using one or more wire(s), the second microelectronic device being structurally coupled with the first microelectronic device via a polymer adhesive;
one or more passive(s) coupled with the first microelectronic device wherein at least one or more passive(s) are enclosed in the polymer adhesive between the first and second microelectronic devices; and
another device electrically coupled with the first microelectronic device.

16. A microelectronic system according to claim 15, wherein the one or more passive(s) are surface mount technology (SMT) passives including resistors, inductors, and capacitors.

17. A microelectronic system according to claim 15, wherein the polymer adhesive comprises a die-attach epoxy that electrically insulates the one or more passive(s).

18. A microelectronic system according to claim 15, wherein the first microelectronic device is a package substrate, the second microelectronic device is an integrated circuit (IC) die, and the other device is memory.

19. A microelectronic system according to claim 15, further comprising:
a spacer coupled with the second microelectronic device; and
a third microelectronic device coupled with the spacer, the third microelectronic device electrically coupled to the first microelectronic device via wire bond attachment using one or more wire(s).

20. A microelectronic system according to claim 19 wherein the spacer comprises dummy Si and the third microelectronic device is an IC die.

21. A microelectronic system according to claim 19, wherein the second microelectronic device, the spacer, the third microelectronic device, the one or more wire bond(s) associated with the second and third microelectronic device, and the one or more passive(s) are enclosed in a mold compound that is coupled to the first microelectronic device.
